(19) United States
(12) Patent Application Publication
(10) Pub. No.: US 2026/0082641 A1
(43) Pub. Date: Mar. 19, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Tatsuya NISHIWAKI, Yokohama Kanagawa (JP); Kentaro ICHINOSEKI, Higashimurayama Tokyo (JP); Hiroki SAKATA, Kawasaki Kanagawa (JP)

(21) Appl. No.: 19/054,482

(22) Filed: Feb. 14, 2025

(30) Foreign Application Priority Data
Sep. 18, 2024 (JP) 2024-161394

(51) Int. Cl. H10D 62/10; H10D 30/01; H10D 30/66; H10D 62/13; H10D 64/00; H10D 64/23; H10D 84/00

(52) U.S. Cl. CPC H10D 62/106; H10D 30/0295; H10D 30/0297; H10D 30/668; H10D 62/153; H10D 64/117; H10D 64/2527; H10D 64/258; H10D 84/146

(57) ABSTRACT

A semiconductor device includes a semiconductor member, a gate electrode, and a source electrode. The semiconductor member has a groove part and a recess. At least a part of the source electrode is disposed inside the recess. The semiconductor member has a drift region and a mesa region. The drift region and the mesa region have first conductivity type impurities. The drift region is positioned on a first side relative to a bottom of the groove part. The mesa region is positioned between a pair of the groove parts in a second direction. The mesa region has a Schottky junction that forms a Schottky junction with the source electrode. The Schottky junction is positioned on a second side relative to an end on the first side of the source electrode and on the second side relative to an end on the first side of the gate electrode.

### CROSS-REFERENCE TO RELATED APPLICATION

This application is based upon and claims the benefit of priority from Japanese Patent Application No. 2024-161394, filed on Sep. 18, 2024, the entire contents of which are incorporated herein by reference.

### FIELD

Embodiments described herein relate generally to semiconductor devices.

### BACKGROUND

There are semiconductor devices such as metal oxide semiconductor field effect transistors (MOSFETs) that have Schottky barrier diodes in elements. In such a structure, a high electric field at the Schottky junction causes a problem of a large leakage current.

### BRIEF DESCRIPTION OF THE DRAWINGS

FIG. 1 is a schematic cross-sectional view of a semiconductor device of a first embodiment.

FIG. 2 is a schematic cross-sectional view of a semiconductor device of a second embodiment.

FIG. 3 is a schematic cross-sectional view of a semiconductor device of a third embodiment when viewed in a thickness direction.

FIG. 4 is a schematic cross-sectional view of a semiconductor device along the line IV-IV in FIG. 3.

FIG. 5 is a schematic cross-sectional view of the semiconductor device along the line V-V in FIG. 3.

FIG. 6 is a schematic cross-sectional view of a semiconductor device of a fourth embodiment.

FIG. 7 is a schematic cross-sectional view of a semiconductor device of a fifth embodiment when viewed in a thickness direction.

FIG. 8 is a schematic cross-sectional view of a semiconductor device along the line IIX-IIX in FIG. 7.

FIG. 9 is a schematic cross-sectional view of the semiconductor device along the line IX-IX in FIG. 7.

FIG. 10 is a schematic cross-sectional view showing a step of forming a gate electrode groove and an internal structure of the gate electrode groove in a semiconductor member in a method of producing the semiconductor device of the fifth embodiment.

FIG. 11 is a schematic cross-sectional view showing a step of causing a first insulating layer to protrude from the upper surface of the semiconductor member in the method of producing the semiconductor device of the fifth embodiment.

FIG. 12 is a schematic cross-sectional view showing a step of forming a sidewall on the upper surface of the semiconductor member in the method of producing the semiconductor device of the fifth embodiment.

FIG. 13 is a schematic cross-sectional view showing a step of forming an insulating film in a second cross section of the semiconductor member in the method of producing the semiconductor device of the fifth embodiment.

FIG. 14 is a schematic cross-sectional view showing a step of forming a preliminary recess on the upper surface of the semiconductor member in the method of producing the semiconductor device of the fifth embodiment.

FIG. 15 is a schematic cross-sectional view showing a step of ion-implanting n-type impurities into the semiconductor member in the method of producing the semiconductor device of the fifth embodiment.

FIG. 16 is a schematic cross-sectional view showing a step of forming a source electrode recess in the semiconductor member in the method of producing the semiconductor device of the fifth embodiment.

FIG. 17 is a schematic cross-sectional view showing a step of removing the wall and the insulating film again in the method of producing the semiconductor device of the fifth embodiment.

FIG. 18 is a schematic cross-sectional view showing a step of forming a second insulating layer on the surface of the semiconductor member in the method of producing the semiconductor device of the fifth embodiment.

FIG. 19 is a schematic cross-sectional view showing a step of forming a contact part inside the source electrode recess in the method of producing the semiconductor device of the fifth embodiment.

FIG. 20 is a schematic cross-sectional view showing a step of partially removing the second insulating layer in the method of producing the semiconductor device of the fifth embodiment.

### DETAILED DESCRIPTION

In semiconductor devices of embodiments, three mutually intersecting directions are defined as a first direction, a second direction and a third direction. One side in the third direction is defined as a first side, and the other side is defined as a second side. The semiconductor device has a semiconductor member, a drain electrode, a gate electrode, a source electrode, a first insulating layer, and a second insulating layer. The semiconductor member has a groove part and a recess. The groove part extends in the first direction, is arranged in the second direction, and is recessed toward the first side. The recess is positioned between a pair of the groove parts in the second direction and is recessed toward the first side. The drain electrode is positioned on the first side of the semiconductor member. The gate electrode is disposed inside the groove part. At least a part of the source electrode is disposed inside the recess. The first insulating layer is disposed inside the groove part. The first insulating layer is positioned between an inner surface of the groove part and the gate electrode. The second insulating layer is disposed inside the recess. The second insulating layer is positioned between an inner surface of the recess and the source electrode. The semiconductor member has a drift region and a mesa region. The drift region has first conductivity type impurities. The drift region is positioned on the first side relative to a bottom of the groove part. The mesa region has first conductivity type impurities. The mesa region is positioned between the pair of groove parts in the second direction. The mesa region has a Schottky junction that forms a Schottky junction with the source electrode. The Schottky junction is positioned on the second side relative to an end on the first side of the source electrode and on the second side relative to an end on the first side of the gate electrode.

Hereinafter, semiconductor devices according to embodiments will be described with reference to the drawings.

### First Embodiment

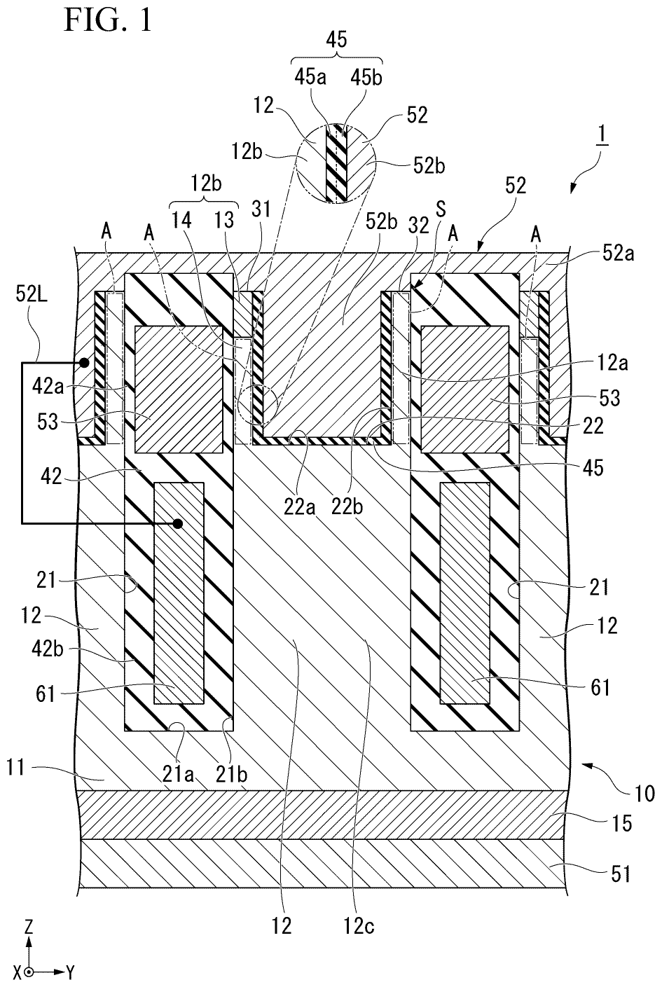

FIG. 1 is a schematic cross-sectional view showing a semiconductor device 1 of a first embodiment.

In the drawings, the X axis, the Y axis, and the Z axis are shown appropriately. The X axis, the Y axis, and the Z axis are perpendicular to each other.

In this specification, a “direction” is defined as a vector including the concept of positive and negative sides that are parallel to a specific axis. Therefore, the concept of “direction” includes two opposite directions (one side and the other side). In the following embodiments, the direction parallel to the X axis corresponds to the “first direction,” the direction parallel to the Y axis corresponds to the “second direction,” and the direction parallel to the Z axis corresponds to the “third direction.” Therefore, the first direction X, the second direction Y and the third direction Z are three mutually intersecting directions. In addition, in the following embodiments, the side (−Z) opposite to the side toward which the Z axis arrow in the third direction Z faces is called a lower side or a first side, and the side (+Z) toward which the Z axis arrow in the third direction Z faces is called an upper side or a second side. In addition, the side (+Y) toward which the Y axis arrow in the second direction Y faces is called a right side or a third side, and the side (−Y) opposite to the side toward which the Y axis arrow in the second direction Y faces is called a left side or a fourth side. Here, in this specification, the concepts of “upper” and “lower” are not necessarily terms that indicate the relationship with the direction of gravity.

In the following description, the notations n, n⁺, and n⁻ indicate relative impurity concentration levels in each conductivity type. That is, n⁺ indicates that the n-type impurity concentration is relatively higher than that of n, and n⁻ indicates that the n-type impurity concentration is relatively lower than that of n.

As shown in FIG. 1, the semiconductor device 1 according to the present embodiment has a semiconductor member 10, a drain electrode 51, a source electrode 52, a gate electrode 53, a field plate (conductive member) 61, a first insulating layer 42, and a second insulating layer 45. In this specification, the thickness direction of the semiconductor device 1 is the third direction Z.

The semiconductor device 1 of the present embodiment is a trench-type metal oxide semiconductor field effect transistor (MOSFET). In addition, the semiconductor device 1 of the present embodiment is a Schottky contact type transistor. The semiconductor device 1 can control a channel layer 14 of the semiconductor member 10 according to the potential of the gate electrode 53. That is, the semiconductor device 1 can control a current that flows between the drain electrode 51 and the source electrode 52 according to the potential of the gate electrode 53.

The semiconductor member 10 contains, for example, at least one selected from the group consisting of silicon (Si), a nitride semiconductor (for example, GaN), silicon carbide (SiC), and an oxide semiconductor (for example, GaO).

In the semiconductor member 10, a plurality of gate electrode grooves (groove parts) 21 and a plurality of source electrode grooves (recesses) 22 are provided. The gate electrode groove 21 and the source electrode groove 22 are recessed toward the lower side (one side in the third direction Z) from the upper surface of the semiconductor member 10. The gate electrode groove 21 and the source electrode groove 22 extend in the first direction X and are arranged alternately in the second direction Y. Therefore, the gate electrode groove 21 is provided on both sides of the source electrode groove 22 in the second direction Y.

On the inner surface of the gate electrode groove 21, a bottom 21a facing upward and a pair of sidewall parts 21b facing each other in the second direction Y are provided. Similarly, on the inner surface of the source electrode groove 22, a bottom 22a facing upward and a pair of sidewall parts 22b facing each other in the second direction Y are provided. The gate electrode groove 21 is formed deeper than the source electrode groove 22.

In the semiconductor member 10, a substrate part 15, a drift region 11, and a mesa region 12 are provided. The substrate part 15, the drift region 11 and the mesa region 12 are all n-type semiconductors. When the semiconductor member 10 contains silicon, first conductivity type impurities may be, for example, pentavalent elements such as phosphorus and arsenic. That is, the first conductivity type impurities are n-type impurities. In the present embodiment, in the semiconductor member 10, no p-type semiconductor is formed. Therefore, the step of producing the semiconductor device 1 can be simplified.

The substrate part 15 is positioned at the lower end of the semiconductor member 10. The substrate part 15 extends along the drain electrode 51 in the first direction X and the second direction Y. The substrate part 15 is, for example, an n⁺ layer.

The drift region 11 is positioned below the bottom 21a of the gate electrode groove 21. The drift region 11 extends along the substrate part 15 in the first direction X and the second direction Y. The drift region 11 is, for example, an n layer or an n⁻ layer.

The mesa region 12 is positioned between the pair of gate electrode grooves 21 in the second direction Y. In the mesa region 12, except for a source layer 13 to be described below, n-type impurities diffuse at the same concentration as in the drift region 11. That is, the mesa region 12 is, except for the source layer 13 to be described below, for example, an n layer or an n⁻ layer.

The mesa region 12 has a first region 12a, a second region 12b and a third region 12c. The first region 12a is positioned between the gate electrode groove 21 and the source electrode groove 22 on the right side (+Y) of the source electrode groove 22. The second region 12b is positioned between the gate electrode groove 21 and the source electrode groove 22 on the left side (−Y) of the source electrode groove 22. The third region 12c is positioned below the first region 12a and the second region 12b. The third region 12c is positioned below the source electrode groove 22. The third region 12c connects the drift region 11 and the first region 12a. In addition, the third region 12c connects the drift region 11 and the second region 12b.

The second region 12b has the source layer 13 and the channel layer 14. The source layer 13 is positioned at the upper end of the second region 12b. That is, the source layer 13 is positioned at the upper end of the semiconductor member 10. The source layer 13 is formed to a certain depth from the upper surface of the semiconductor member 10. The channel layer 14 is positioned below the source layer 13. The channel layer 14 connects the source layer 13 and the third region 12c. In the source layer 13, n-type impurities diffuse at a higher concentration than in the drift region 11. On the other hand, the channel layer 14 has n-type impurities at the same concentration as in the drift region 11. The source layer 13 is, for example, an n⁺ layer.

The drain electrode 51, the source electrode 52, the gate electrode 53, and the field plate 61 each extend in the first direction X. The gate electrode 53 and the source electrode 52 are arranged in the second direction Y. The gate electrode 53 and the field plate 61 are arranged in the third direction Z.

The drain electrode 51 is provided on the lower surface of the semiconductor member 10. The drain electrode 51 contains, for example, Al, Cu, Mo, W, Ta, Co, Ru, Ti and Pt.

At least a part of the source electrode 52 is disposed inside the source electrode groove 22. The source electrode 52 has an electrode part 52a and a contact part 52b. The electrode part 52a is positioned above the upper surface of the semiconductor member 10. The contact part 52b is disposed inside the source electrode groove 22.

The metallic material constituting the source electrode 52 has a higher work function than the semiconductors constituting the drift region 11 and the mesa region 12. Therefore, the source electrode 52 can form a Schottky junction with the first region 12a. In the present embodiment, the source electrode 52 is in contact with the first region 12a at the electrode part 52a. In addition, a part of the first region 12a that is in contact with the electrode part 52a and forms a Schottky junction is called a Schottky junction 32. That is, the first region 12a has the Schottky junction 32.

Here, in this specification, when work functions of a plurality of parts are compared, the energy levels of the parts are compared.

As described above, the source layer 13 contains n-type impurities at a high concentration. Therefore, the source electrode 52 can form an ohmic junction with the source layer 13. In the present embodiment, the source electrode 52 is in contact with the source layer 13 at the electrode part 52a. In addition, a part of the source layer 13 that is in contact with the electrode part 52a and forms an ohmic junction is called an ohmic junction 31. That is, the source layer 13 has the ohmic junction 31.

For example, when the semiconductor member 10 contains silicon, the source electrode 52 contains, for example, at least one selected from the group consisting of Ti, TiN, W, Mo, Ta, Zr, Al, Sn, V, Re, Os, Ir, Pt, Pd, Rh, Ru, Nb, Sr and Hf.

Here, in the present embodiment, a case in which the electrode part 52a and the contact part 52b of the source electrode 52 are made of the same material has been described. However, the electrode part 52a and the contact part 52b may be made of different materials.

The gate electrode 53 is disposed inside the gate electrode groove 21. The gate electrode 53 contains, for example, polysilicon. The gate electrode 53 is insulated from the semiconductor member 10. The gate electrode 53 and the contact part 52b overlap in the second direction Y. The upper end of the gate electrode 53 is positioned lower than the upper end of the contact part 52b. The lower end of the gate electrode 53 is positioned lower than the lower end of the contact part 52b.

The field plate 61 is disposed inside the gate electrode groove 21. The field plate 61 is positioned below the gate electrode 53. The field plate 61 is insulated from the gate electrode 53 and the semiconductor member 10. In addition, the field plate 61 is electrically connected to the source electrode 52 via, for example, a wire 52L. Thereby, the field plate 61 and the source electrode 52 are at the same potential.

When the field plate 61 is provided in the gate electrode groove 21, it is possible to alleviate the electric field strength of the drift region 11. Thereby, it is possible to improve withstand voltage characteristics between the drain electrode 51 and the source electrode 52 of the semiconductor member 10. In addition, according to improvement in withstand voltage, the impurity concentration of the drift region 11 can be set to be high, and the on-resistance of the semiconductor device 1 can be reduced.

The first insulating layer 42 is disposed inside the gate electrode groove 21. The first insulating layer 42 includes a gate insulating film 42a and a field plate insulating film 42b. The gate insulating film 42a is positioned between the gate electrode 53 and the mesa region 12 of the semiconductor member 10. On the other hand, the field plate insulating film 42b is positioned between the field plate 61 and the gate electrode 53, between the field plate 61 and the mesa region 12, and between the field plate 61 and the drift region 11 of the semiconductor member 10.

The second insulating layer 45 is formed on the inner surface of the source electrode groove 22. In the present embodiment, the second insulating layer 45 covers the entire inner surface of the source electrode groove 22 (that is, the entire sidewall part 22b and the entire bottom 22a). The second insulating layer 45 is positioned between the contact part 52b and the mesa region 12 of the semiconductor member 10, and insulates the contact part 52b from the mesa region 12.

The second insulating layer 45 of the present embodiment has a first layer 45a and a second layer 45b laminated on each other. The first layer 45a is positioned on the side of the mesa region 12 between the mesa region 12 and the contact part 52b. On the other hand, the second layer 45b is positioned on the side of the contact part 52b between the mesa region 12 and the contact part 52b. In the present embodiment, the first layer 45a is formed of, for example, silicon oxide (SiO₂), and the second layer 45b is formed of, for example, aluminum oxide (Al₂O₃). Alternatively, the first layer 45a may be formed of lanthanum (III) oxide (La₂O₃), and the second layer 45b may be formed of silicon oxide (SiO₂). In addition, the first layer 45a may be formed of lanthanum (III) oxide (La₂O₃), and the second layer 45b may be formed of aluminum oxide (Al₂O₃).

In the second insulating layer 45 of the present embodiment, a dipole effect can be expected. That is, in the second insulating layer 45, polarization occurs in each of the first layer 45a and the second layer 45b. Thereby, an electric field is generated inside the second insulating layer 45, and depletion is promoted in a part (for example, the first region 12a) of the mesa region 12 that faces the first layer 45a.

Next, the principle of operating the semiconductor device 1 of the present embodiment will be described.

In the present embodiment, the electrode part 52a and the source layer 13 of the second region 12b form an ohmic junction. Therefore, the electrode part 52a and the second region 12b are electrically connected. In addition, since the work function of the contact part 52b is higher than the electron affinity of the channel layer 14, a depletion layer is formed in the channel layer 14 of the second region 12b. In addition, the first layer 45a and the second layer 45b of the second insulating layer 45 promote the depletion of the channel layer 14 according to mutually polarizing dipole effects. Therefore, when no voltage is applied to the gate electrode 53, the depletion layer allows an off state in which no current flows through the channel layer 14 to be obtained. When the potential of the gate electrode 53 is controlled, an electron accumulation layer is formed in the channel layer 14, and an on state in which a drain current flows through the channel layer 14 is obtained. Therefore, in the semiconductor device 1, the current between the drain electrode 51 and the electrode part 52a is controlled by the potential of the gate electrode 53. Here, the potential of the gate electrode 53 is the potential based on the potential of the electrode part 52a.

In the present embodiment, the electrode part 52a and the first region 12a form a Schottky junction. Therefore, the electrode part 52a and the first region 12a function as a Schottky barrier diode S, and allow a current to flow from the electrode part 52a to the first region 12a.

Here, when a strong electric field is formed in the first region 12a that forms a Schottky junction with the source electrode 52, the leakage current of the Schottky barrier diode S becomes large. According to the present embodiment, the Schottky junction 32 is provided at the upper end of the first region 12a. The upper end of the first region 12a is surrounded by the gate electrode 53 and the contact part 52b and the electrode part 52a of the source electrode 52. Therefore, at the upper end of the first region 12a, a strong electric field is unlikely to be generated, and the leakage current of the Schottky barrier diode S can be reduced.

Here, in the present embodiment, the Schottky junction 32 is preferably positioned above the upper end of the gate electrode 53. When the Schottky junction 32 is disposed at a position overlapping the gate electrode 53 in the second direction Y, the gate electrode 53 and the contact part 52b come close to each other. In this case, it becomes difficult to secure insulation between the gate electrode 53 and the contact part 52b, and it becomes necessary to increase the thickness of the first insulating layer 42. When the Schottky junction 32 is disposed above the upper end of the gate electrode 53, it becomes easier to secure insulation between the contact part 52b and the gate electrode 53. This makes it possible to thin the first insulating layer 42, reduce the channel resistance of the semiconductor device 1, and prevent the device from becoming large.

In the present embodiment, the Schottky junction 32 is disposed on the same plane as the ohmic junction 31. However, the Schottky junction 32 may be positioned, for example, below the ohmic junction 31.

Next, operation effects of the present embodiment will be described.

In the semiconductor device 1 of the present embodiment, three mutually intersecting directions are defined as a first direction X, a second direction Y and a third direction Z, and one side in the third direction Z is defined as a lower side (−Z), and the other side is defined as an upper side (+Z). The semiconductor device 1 has the semiconductor member 10, the drain electrode 51, the gate electrode 53, the source electrode 52, the first insulating layer 42, and the second insulating layer 45. The semiconductor member 10 has the plurality of gate electrode grooves 21 and the source electrode grooves 22. The plurality of gate electrode grooves 21 extend in the first direction X, are arranged in the second direction Y, and are recessed toward the lower side (−Z). The source electrode groove 22 is positioned between the pair of gate electrode grooves 21 in the second direction Y and is recessed toward the lower side (−Z). The drain electrode 51 is positioned on the lower side (−Z) of the semiconductor member 10. The gate electrode 53 is disposed inside the gate electrode groove 21. At least a part of the source electrode 52 is disposed inside the source electrode groove 22. The first insulating layer 42 is disposed inside the gate electrode groove 21. The first insulating layer 42 is positioned between the inner surface of the gate electrode groove 21 and the gate electrode 53. The second insulating layer 45 is disposed inside the source electrode groove 22. The second insulating layer 45 is positioned between the inner surface of the source electrode groove 22 and the source electrode 52. The semiconductor member 10 has the drift region 11 and the mesa region 12. The drift region 11 has n-type impurities. The drift region 11 is positioned on the side (−Z) below the bottom of the gate electrode groove 21. The mesa region 12 has n-type impurities. The mesa region 12 is positioned between the pair of gate electrode grooves 21 in the second direction Y. The mesa region 12 has the Schottky junction 32 that forms a Schottky junction with the source electrode 52. The Schottky junction 32 is positioned on the side (+Z) above the end on the lower side (−Z) of the source electrode 52 and on the side (+Z) above the end on the lower side (−Z) of the gate electrode 53.

With such a configuration, the source electrode 52 can form a Schottky junction with the mesa region 12 to constitute the Schottky barrier diode S. When the electric field strength of the Schottky junction 32 is high, the Schottky barrier diode S tends to have a large leakage current. With such a configuration, the Schottky junction 32 is positioned above the lower ends of both the source electrode 52 and the gate electrode 53. Therefore, the Schottky junction 32 is provided in a region of the mesa region 12 that is interposed between the source electrode 52 and the gate electrode 53 (in the present embodiment, the first region 12a). Therefore, it is possible to alleviate the electric field strength of the first region 12a and reduce the leakage current of the Schottky barrier diode S.

In the semiconductor device 1 of the present embodiment, the mesa region 12 has the source layer 13 having a higher n-type impurity concentration than the drift region 11 at the upper side (+Z) end. The source layer 13 has the ohmic junction 31 that forms an ohmic junction with the source electrode 52. With such a configuration, a current can flow from the mesa region 12 in the on-state to the source electrode 52 via the ohmic junction 31.

In the semiconductor device 1 of the present embodiment, one side in the second direction Y is defined as a right side (+Y), and the other side is defined as a left side (−Y). The mesa region 12 has the first region 12a and the second region 12b. The first region 12a is positioned on the right side (+Y) of the source electrode groove 22. The second region 12b is positioned on the left side (−Y) of the source electrode groove 22. The second region 12b has the source layer 13. The Schottky junction 32 is provided in the first region 12a.

With such a configuration, with a simple structure, the first region 12a and the second region 12b can be separated with the source electrode groove 22 therebetween. Thereby, it is possible to constitute the semiconductor device 1 in which the channel layer 14 and the Schottky barrier diode S are disposed in one mesa region 12 at a high density.

In the semiconductor device 1 of the present embodiment, the Schottky junction 32 is positioned on the side (+Z) above the end on the upper side (+Z) of the gate electrode 53. With such a configuration, it becomes easier to secure the distance between the gate electrode 53 and the contact part 52b. This makes it easier to secure insulation between the gate electrode 53 and the contact part 52b, make the first insulating layer 42 thin, reduce the channel resistance of the semiconductor device 1, and reduce the size of the device.

The semiconductor device 1 of the present embodiment has the field plate 61. The field plate 61 is positioned inside the gate electrode groove 21 and between the gate electrode 53 and the drift region 11. The field plate 61 is insulated from the gate electrode 53. The field plate 61 is electrically connected to the source electrode 52. With such a configuration, when the field plate 61 is provided, it is possible to alleviate the electric field strength of the drift region 11 and improve withstand voltage characteristics of the semiconductor device 1. In addition, when the field plate 61 is provided, it is possible to alleviate the electric field strength of the first region 12a and reduce the leakage current of the Schottky barrier diode S. Here, in the present embodiment, a case in which the semiconductor device 1 has the field plate 61 has been described, but the semiconductor device 1 may not have the field plate 61.

The second insulating layer 45 of the present embodiment has the first layer 45a and the second layer 45b that are polarized. Thereby, due to the dipole effect, the depletion of the channel layer 14 becomes significant, and unless a large voltage is applied to the gate electrode 53, a current is unable to flow (that is, it is turned on) through the channel layer 14. That is, according to the present embodiment, when the second insulating layer 45 has the first layer 45a and the second layer 45b that are polarized, it is possible to increase a gate threshold voltage.

In the semiconductor device 1 of the present embodiment, a case in which the concentrations of n-type impurities in the first region 12a, the channel layer 14 of the second region 12b, the third region 12c, and the drift region 11 are equal to each other has been described. However, the concentrations of n-type impurities in the first region 12a and the channel layer 14 may be adjusted. For example, the concentration of n-type impurities in a region A surrounded by the imaginary line (double-dashed line) in FIG. 1 may be lower than the concentration of n-type impurities in the drift region 11. The region A is, for example, an n⁻ layer. The region A includes the first region 12a and the channel layer 14 of the second region 12b.

In the present embodiment, when the concentration of n-type impurities in the first region 12a is set to be lower than the concentration of n-type impurities in the drift region 11, it is possible to further alleviate the electric field strength of the first region 12a. Thereby, it is possible to further reduce the leakage current of the Schottky barrier diode S.

In the present embodiment, when the concentration of n-type impurities in the channel layer 14 of the second region 12b is set to be lower than the concentration of n-type impurities in the drift region 11, the channel layer 14 is more easily depleted in the off state. Thereby, it is possible to increase the gate threshold voltage.

### Second Embodiment

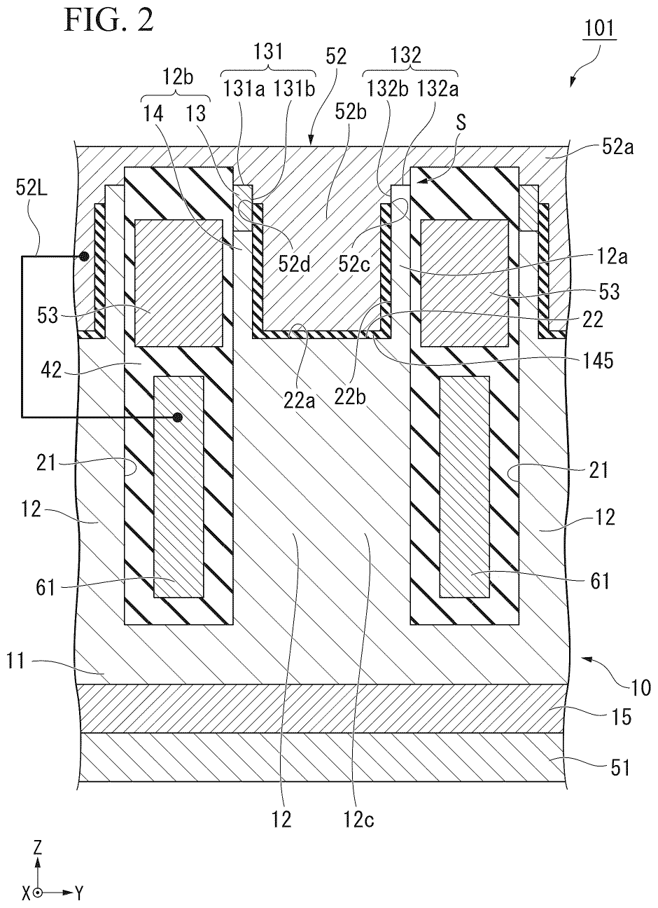

FIG. 2 is a schematic cross-sectional view showing a semiconductor device 101 of a second embodiment.

The semiconductor device 101 of the second embodiment differs from that of the first embodiment mainly in the range in which a Schottky junction 132 and an ohmic junction 131 are formed.

Here, in the following embodiments, the same components as those in the embodiments described above will be denoted with the same reference numerals and descriptions thereof will be omitted.

As in the above embodiment, in the semiconductor member 10, the gate electrode groove 21 and the source electrode groove 22 are provided. In addition, on the inner surface of the source electrode groove 22, a second insulating layer 145 is formed. In addition, the contact part 52b is disposed inside the source electrode groove 22.

In the present embodiment, the second insulating layer 145 is formed on the inner surface of the source electrode groove 22 except for the upper end of the sidewall part 22b. That is, the second insulating layer 145 is not formed at the upper end of the sidewall part 22b. That is, the upper end of the inner surface of the source electrode groove 22 is exposed from the second insulating layer 145. Therefore, the upper end of the contact part 52b is in contact with each of the upper end of the first region 12a and the upper end of the second region 12b (the source layer 13). Here, a part of the upper end of the contact part 52b that is in contact with the first region 12a is called a first part 52c, and a part thereof that is in contact with the source layer 13 is called a second part 52d. That is, the contact part 52b has the first part 52c and the second part 52d. The first part 52c is positioned at the upper end of the surface facing the right side (+Y) of the contact part 52b. The second part 52d is positioned at the upper end of the surface facing the left side (−Y) of the contact part 52b.

In the present embodiment, the first part 52c forms a Schottky junction with the first region 12a at the upper end of the source electrode groove 22. Therefore, the first region 12a of the present embodiment forms a Schottky junction not only with the lower surface of the electrode part 52a but also with the upper end of the surface facing the right side (+Y) of the contact part 52b.

According to the present embodiment, the Schottky junction 132 has a first junction 132a joined to the electrode part 52a and a second junction 132b joined to the first part 52c of the contact part 52b. The first junction 132a extends along a plane (X-Y plane) perpendicular to the third direction Z. The second junction 132b extends along a plane (X-Z plane) perpendicular to the second direction Y. According to the present embodiment, a large junction area of the Schottky junction 132 can be secured without increasing the size of the semiconductor device 101, and the electrical resistance of the Schottky junction 132 can be reduced.

As in the above embodiment, the Schottky junction 132 of the present embodiment is positioned above the lower ends of both the source electrode 52 and the gate electrode 53. Therefore, it is possible to alleviate the electric field strength of the first region 12a and reduce the leakage current of the Schottky barrier diode S.

In the present embodiment, the second part 52d forms an ohmic junction with the source layer 13 at the upper end of the source electrode groove 22. Therefore, the source layer 13 of the present embodiment forms a ohmic junction not only with the lower surface of the electrode part 52a but also with the upper end of the surface facing the left side (−Y) of the contact part 52b.

According to the present embodiment, the ohmic junction 131 has a third junction 131a joined to the electrode part 52a and a fourth junction 131b joined to the second part 52d of the contact part 52b. The third junction 131a extends along a plane (X-Y plane) perpendicular to the third direction Z. The fourth junction 131b extends along a plane (X-Z plane) perpendicular to the second direction Y. According to the present embodiment, a large junction area of the ohmic junction 131 can be secured without increasing the size of the semiconductor device 101, and the electrical resistance of the ohmic junction 131 can be reduced.

In addition, in the present embodiment, the lower ends of the second junction 132b and the fourth junction 131b are preferably positioned on the side (+Z) above the upper end of the gate electrode 53. In this case, the second junction 132b and the gate electrode 53 can be prevented from being arranged in the second direction Y. Thereby, it is easier to secure insulation between the gate electrode 53 and the first part 52c. In addition, the fourth junction 131b and the gate electrode 53 can be prevented from being arranged in the second direction Y. Thereby, it is easier to secure insulation between the gate electrode 53 and the second part 52d. According to the present embodiment, it is possible to reduce the electrical resistance of the Schottky junction 132 and the ohmic junction 131, make the first insulating layer 42 thin, and reduce the size of the semiconductor device 101.

Here, in the semiconductor device 101 of the present embodiment, as in the first embodiment, the concentrations of n-type impurities in the first region 12a and the channel layer 14 of the second region 12b may be lower than the concentration of n-type impurities in the drift region 11.

### Third Embodiment

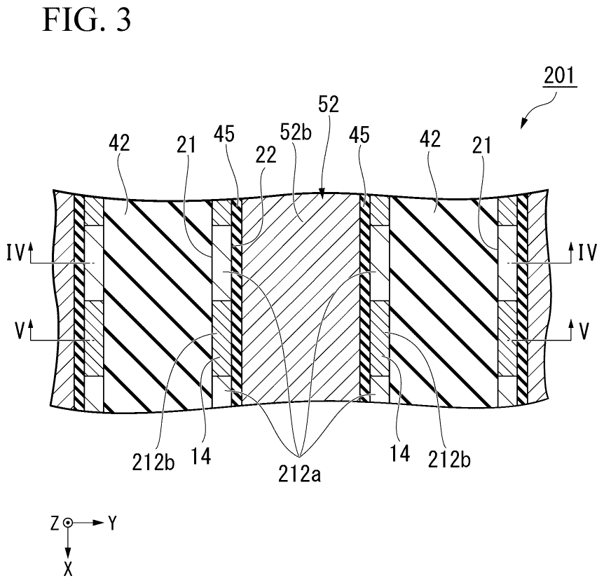

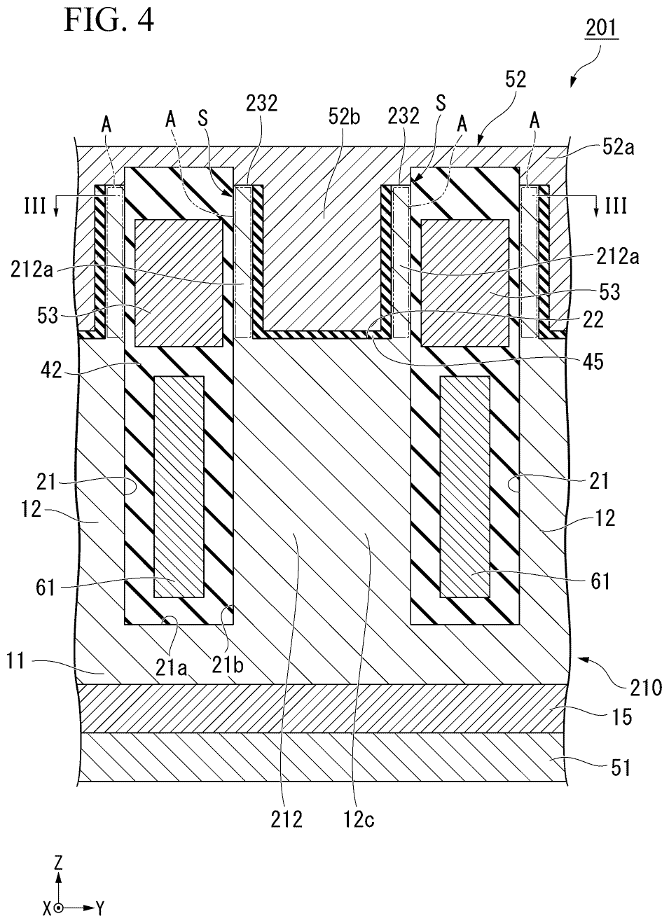

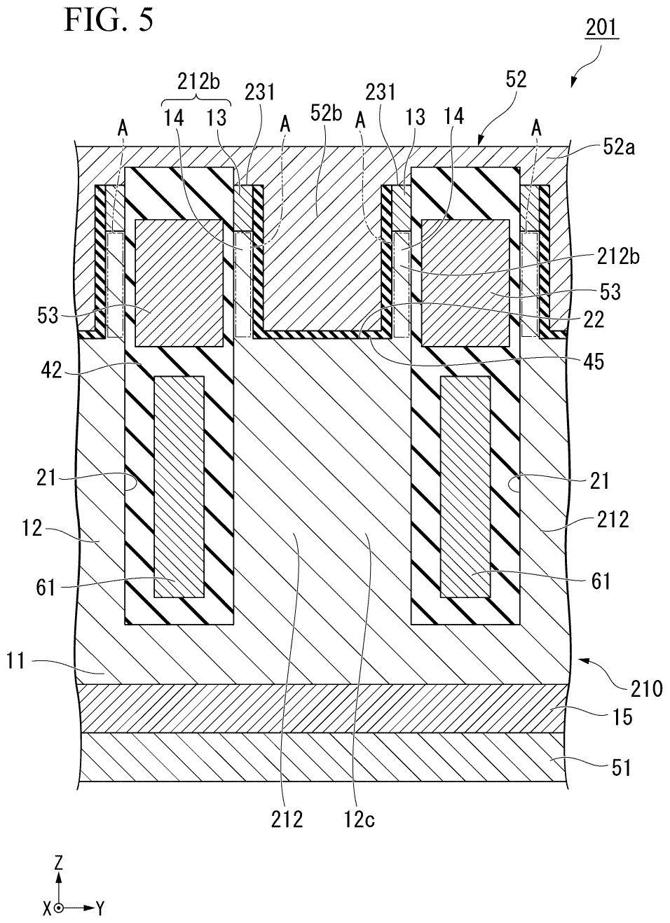

FIG. 3 is a schematic cross-sectional view showing a semiconductor device 201 of a third embodiment when viewed in a thickness direction. FIG. 4 is a schematic cross-sectional view showing the semiconductor device 201 along the line IV-IV in FIG. 3. FIG. 5 is a schematic cross-sectional view showing the semiconductor device 201 along the line V-V in FIG. 3.

The semiconductor device 201 of the third embodiment differs from that of the first embodiment mainly in the disposition of a Schottky junction 232 and an ohmic junction 231.

In the semiconductor device 201 of the present embodiment, the cross section shown in FIG. 4 and the cross section shown in FIG. 5 are alternately formed in the first direction X. Hereinafter, the cross section shown in FIG. 4 will be referred to as a first cross section, and the cross section shown in FIG. 5 will be referred to as a second cross section.

As shown in FIG. 4 and FIG. 5, in the semiconductor device 201 of the present embodiment, in a semiconductor member 210, the substrate part 15, the drift region 11, and a mesa region 212 are provided. The mesa region 212 is positioned between the pair of gate electrode grooves 21. The mesa region 212 has a first region 212a provided in the first cross section (FIG. 4), a second region 212b provided in the second cross section (FIG. 5), and the third region 12c provided in both the first cross section and the second cross section. The third region 12c is positioned below the source electrode groove 22. The third region 12c connects the drift region 11 and the first region 212a. In addition, the third region 12c connects the drift region 11 and the second region 212b.

In the first cross section shown in FIG. 4, the first region 212a is positioned between the gate electrode groove 21 and the source electrode groove 22 on the right side (+Y) and the left side (−Y) of the source electrode groove 22. The upper end of the first region 212a is in contact with the electrode part 52a. In a part of the first region 212a that is in contact with the electrode part 52a, the Schottky junction 232 is provided. In the first cross section, the Schottky junction 232 is provided on the right side and the left side of the source electrode groove 22.

In the second cross section shown in FIG. 5, the second region 212b is positioned between the gate electrode groove 21 and the source electrode groove 22 on the right side (+Y) and the left side (−Y) of the source electrode groove 22. The second region 212b has the source layer 13 and the channel layer 14. The source layer 13 is positioned at the upper end of the second region 212b. The upper end of the source layer 13 is in contact with the electrode part 52a. In a part of the source layer 13 that is in contact with the electrode part 52a, the ohmic junction 231 is provided. In the second cross section, the ohmic junction 231 is provided on the right side and the left side of the source electrode groove 22.

According to the semiconductor device 201 of the present embodiment, as in the above embodiment, the Schottky junction 232 is positioned above the lower ends of both the source electrode 52 and the gate electrode 53. Therefore, it is possible to alleviate the electric field strength of the first region 212a and reduce the leakage current of the Schottky barrier diode S.

In the semiconductor device 201 of the embodiment, the mesa region 212 has the first region 212a and the second region 212b. The first region 212a and the second region 212b are positioned between the gate electrode groove 21 and the source electrode groove 22 in the second direction Y. The first region 212a and the second region 212b are arranged in the first direction X. The second region 212b has the source layer 13. The Schottky junction 232 is provided in the first region 212a.

According to the present embodiment, the Schottky junction 232 and the ohmic junction 231 can be arranged in the first direction X. In the present embodiment, the ratio of the Schottky junction 232 and the ohmic junction 231 in the first direction X may be changed. In this case, it is possible to easily adjust the ratio of the resistance values of the Schottky junction 232 and the ohmic junction 231. For example, when the length of the ohmic junction 231 in the first direction X is set to be larger than the length of the Schottky junction 232 in the first direction X, it is possible to reduce the resistance value of the Schottky junction 232. In addition, in this case, since the length of the channel layer 14 in the first direction X is also increased, it is possible to constitute the semiconductor device 201 with a low on-resistance.

Here, in the semiconductor device 201 of the present embodiment, in the first cross section (refer to FIG. 4), the first region 212a is disposed on the right side and the left side of the source electrode groove 22. In addition, in the second cross section (refer to FIG. 5), the second region 212b is disposed on the right side and the left side of the source electrode groove 22. That is, in the present embodiment, the position of the first region 212a positioned on the right side of the source electrode groove 22 and the position of the first region 212a positioned on the left side thereof overlap in the second direction Y. In addition, in the present embodiment, the position of the second region 212b positioned on the right side of the source electrode groove 22 and the position of the second region 212b positioned on the left side overlap in the second direction Y. However, the first regions 212a positioned on the right side and the left side of the source electrode groove 22 may be shifted from each other in the first direction X. Similarly, the second regions 212b positioned on the right side and the left side of the source electrode groove 22 may be shifted from each other in the first direction X. For example, in the first cross section, the first region 212a may be disposed on the right side of the source electrode groove 22 and the second region 212b may be disposed on the left side, and in the second cross section, the second region 212b may be disposed on the right side of the source electrode groove 22, and the first region 212a may be disposed on the left side. In this case, since a current can flow over a wider range in the first direction X, it is possible to further reduce the on-resistance.

In a general semiconductor device, a current flowing through the channel layer in the on state tends to concentrate near the corners of the source electrode groove. According to the present embodiment, since the first region 212a and the second region 212b are arranged in the first direction X, a current flowing through the channel layer 14 in the on state can spread and flow below the channel layer 14 in the first direction X. Thereby, the current flows not only through the third region 12c in the second cross section (FIG. 5) but also through the third region 12c in the first cross section (FIG. 4). According to the present embodiment, the current concentration in the mesa region 212 is alleviated and the on-resistance of the semiconductor device 201 is reduced.

In the semiconductor device 201 of the present embodiment, the concentrations of n-type impurities in the first region 212a and the second region 212b may be adjusted. For example, the concentration of n-type impurities in the region A surrounded by the imaginary line (double-dashed line) shown in FIG. 4 and FIG. 5 may be lower than the concentration of n-type impurities in the drift region 11. When the concentration of n-type impurities in the first region 212a is set to be lower than the concentration of n-type impurities in the drift region 11 it is possible to further alleviate the electric field strength of the first region 212a. In addition, when the concentration of n-type impurities in the channel layer 14 of the second region 212b is set to be lower than the concentration of n-type impurities in the drift region 11, the channel layer 14 is more easily depleted in the off state.

### Fourth Embodiment

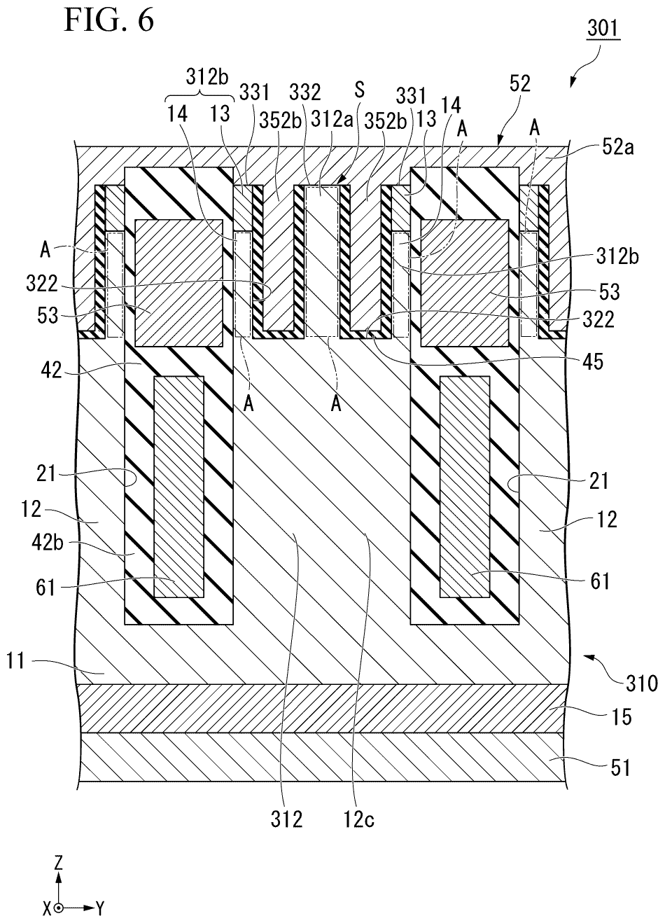

FIG. 6 is a schematic cross-sectional view showing a semiconductor device 301 of a fourth embodiment.

The semiconductor device 301 of the fourth embodiment differs from that of the first embodiment mainly in the number of source electrode grooves 322.

As in the above embodiment, in a semiconductor member 310, the gate electrode groove 21 and the source electrode groove (recess) 322 are provided. In addition, in the present embodiment, the pair of source electrode grooves 322 are disposed between the pair of gate electrode grooves 21 arranged in the second direction Y. The second insulating layer 45 is formed on the inner surfaces of the pair of source electrode grooves 322. In addition, a contact part 352b is provided inside the pair of source electrode grooves 322. Therefore, the pair of contact parts 352b arranged in the second direction Y are disposed between the pair of gate electrodes 53 arranged in the second direction Y.

In the semiconductor device 301 of the present embodiment, in the semiconductor member 310, the substrate part 15, the drift region 11 and a mesa region 312 are provided. The mesa region 312 is positioned between the pair of gate electrode grooves 21. The mesa region 312 has a first region 312a, a pair of second regions 312b, and the third region 12c. The third region 12c is positioned below the pair of source electrode grooves 322. The third region 12c connects the drift region 11 and the first region 312a. In addition, the third region 12c connects the drift region 11 and the second region 312b.

The first region 312a is positioned between the pair of source electrode grooves 322. The upper end of the first region 312a is in contact with the electrode part 52a. In a part of the first region 312a that is in contact with the electrode part 52a, a Schottky junction 332 is provided. The Schottky junction 332 is provided between the pair of source electrode grooves 322.

The second regions 312b are positioned on the right side (+Y) and the left side (−Y) of the pair of source electrode grooves 322, respectively. One of the pair of second regions 312b that is positioned on the right side (+Y) is positioned between one of the pair of source electrode grooves 322 that is positioned on the right side (+Y) and the gate electrode groove 21. The other of the pair of second regions 312b that is positioned on the left side (−Y) is positioned between the other of the pair of source electrode grooves 322 that is positioned on the left side (−Y) and the gate electrode groove 21. The second region 312b has the source layer 13 and the channel layer 14. The source layer 13 is positioned at the upper end of the second region 312b. The upper end of the source layer 13 is in contact with the electrode part 52a. In a part of the source layer 13 that is in contact with the electrode part 52a, an ohmic junction 331 is provided. The ohmic junction 331 is provided on the right side and the left side of the pair of source electrode grooves 322.

As in the above embodiment, the Schottky junction 332 of the present embodiment is positioned above the lower ends of both the source electrode 52 and the gate electrode 53. Therefore, it is possible to alleviate the electric field strength of the first region 312a and reduce the leakage current of the Schottky barrier diode S. Here, in the present embodiment, the Schottky junction 332 is disposed on the same plane as the ohmic junction 331. However, the Schottky junction 332 may be positioned, for example, below the ohmic junction 331.

In the semiconductor device 301 of the present embodiment, the semiconductor member 310 has the pair of source electrode grooves 322 arranged in the second direction Y, which are positioned between the pair of gate electrode grooves 21. The mesa region 312 has the first region 312a and the pair of second regions 312b. The first region 312a is positioned between the pair of source electrode grooves 322. The second region 312b is positioned on the right side (+Y) and the left side (−Y) of the pair of source electrode grooves. The second region 312b has the source layer 13. The Schottky junction 332 is provided in the first region 312a. According to the semiconductor device 301 of the present embodiment, two channel layers 14 can be disposed in one mesa region 312. This makes it possible to reduce the resistance value of the channel layer 14 and provide the semiconductor device 301 with a low on-resistance.

In the semiconductor device 301 of the present embodiment, the concentrations of n-type impurities in the first region 312a and the second region 312b may be adjusted. For example, the concentration of n-type impurities in the region A surrounded by the imaginary line (double-dashed line) shown in FIG. 6 may be lower than the concentration of n-type impurities in the drift region 11. When the concentration of n-type impurities in the first region 312a is set to be lower than the concentration of n-type impurities in the drift region 11, it is possible to further alleviate the electric field strength of the first region 312a. In addition, when the concentration of n-type impurities in the channel layer 14 of the second region 312b is set to be lower than the concentration of n-type impurities in the drift region 11, the channel layer 14 is more easily depleted in the off state.

### Fifth Embodiment

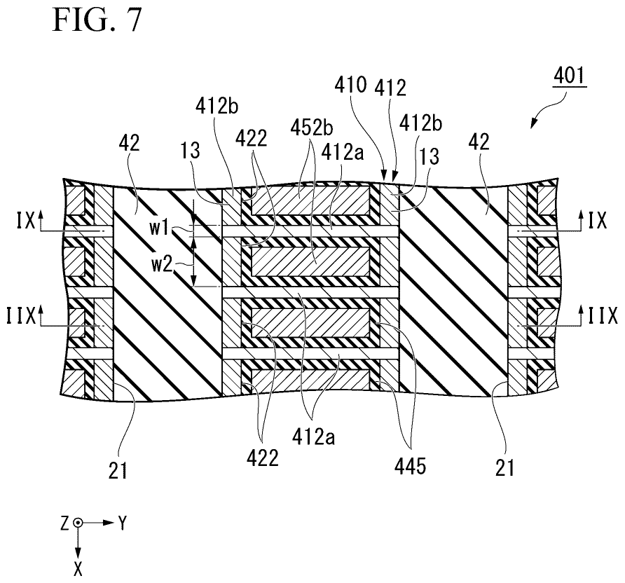

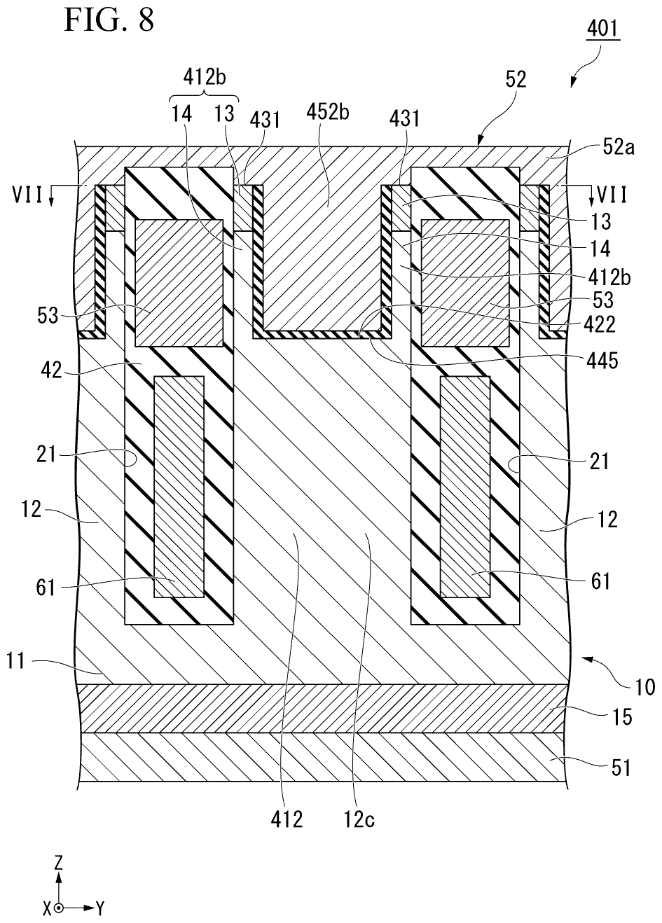

FIG. 7 is a schematic cross-sectional view showing a semiconductor device 401 of a fifth embodiment when viewed in a thickness direction. FIG. 8 is a schematic cross-sectional view showing the semiconductor device 401 along the line IIX-IIX in FIG. 7.

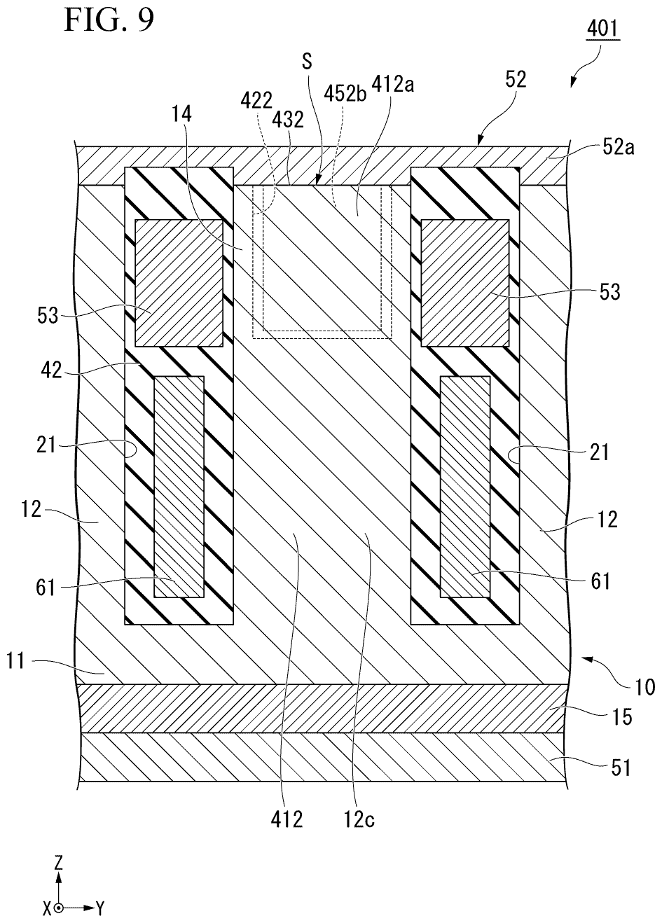

FIG. 9 is a schematic cross-sectional view showing the semiconductor device 401 along the line IX-IX in FIG. 7.

The semiconductor device 401 of the fifth embodiment differs from that of the first embodiment mainly in the disposition of a Schottky junction 432 and an ohmic junction 431.

In the semiconductor device 401 of the present embodiment, the cross section shown in FIG. 8 and the cross section shown in FIG. 9 are alternately formed in the first direction X. Hereinafter, the cross section shown in FIG. 8 will be referred to as a first cross section, and the cross section shown in FIG. 9 will be referred to as a second cross section.

As shown in FIG. 7, in a semiconductor member 410, a plurality of gate electrode grooves 21 and a plurality of source electrode recesses (recesses) 422 are provided. As in the above embodiment, the plurality of gate electrode grooves 21 are arranged in the second direction. In addition, the plurality of source electrode recesses 422 are arranged between the pair of gate electrode grooves 21 in the first direction X. A second insulating layer 445 is formed on the inner surfaces of the plurality of source electrode recesses 422. In addition, a contact part 452b is provided inside the plurality of source electrode recesses 422. Therefore, the plurality of contact parts 452b arranged in the first direction X are disposed between the pair of gate electrodes 53 arranged in the second direction Y.

As shown in FIG. 8 and FIG. 9, in the semiconductor device 401 of the present embodiment, in the semiconductor member 410, the substrate part 15, the drift region 11 and a mesa region 412 are provided. The mesa region 412 is positioned between the pair of gate electrode grooves 21. The mesa region 412 has a first region 412a provided in the second cross section (FIG. 9), a second region 412b provided in the first cross section (FIG. 8), and the third region 12c provided in both the first cross section and the second cross section. The third region 12c is positioned below the source electrode recess 422. The third region 12c connects the drift region 11 and the first region 412a. In addition, the third region 12c connects the drift region 11 and the second region 412b.

As shown in FIG. 7, the first region 412a is positioned between the source electrode recesses 422 arranged in the first direction X. As shown in FIG. 9, regarding the first region 412a, the upper end of the first region 412a is in contact with the electrode part 52a. In a part of the first region 412a that is in contact with the electrode part 52a, the Schottky junction 432 is provided.

In the first cross section shown in FIG. 8, the second region 412b is positioned between the gate electrode groove 21 and the source electrode recess 422 on the right side (+Y) and the left side (−Y) of the source electrode recess 422. The second region 412b has the source layer 13 and the channel layer 14. The source layer 13 is positioned at the upper end of the second region 412b. The upper end of the source layer 13 is in contact with the electrode part 52a. In a part of the source layer 13 that is in contact with the electrode part 52a, the ohmic junction 431 is provided. In the first cross section, the ohmic junction 431 is provided on the right side and the left side of the source electrode recess 422.

According to the semiconductor device 401 of the present embodiment, as in the above embodiment, the Schottky junction 432 is positioned above the lower ends of both the source electrode 52 and the gate electrode 53. Therefore, it is possible to alleviate the electric field strength of the first region 412a and reduce the leakage current of the Schottky barrier diode S. Here, in the present embodiment, the Schottky junction 432 is disposed on the same plane as the ohmic junction 431. However, the Schottky junction 432 may be positioned, for example, below the ohmic junction 431.

In the semiconductor device 401 of the embodiment, the semiconductor member 410 has a plurality of source electrode recesses 422. The plurality of source electrode recesses 422 are positioned between the pair of gate electrode grooves 21. The plurality of source electrode recesses 422 are arranged in the first direction X. The mesa region 412 includes the first region 412a and the second region 412b. The first region 412a is positioned between the plurality of source electrode recesses 422 in the first direction X. The second region 412b is positioned between the gate electrode groove 21 and the source electrode recess 422 in the second direction Y. The second region 412b has the source layer 13. The Schottky junction 432 is provided in the first region 412a.

According to the present embodiment, the first region 412a and the second region 412b are arranged in the first direction X. Therefore, a current flowing through the channel layer 14 in the on state can spread and flow below the channel layer 14 in the first direction X. Thereby, the current flows not only through the third region 12c in the first cross section (FIG. 8) but also through the third region 12c in the second cross section (FIG. 9). According to the present embodiment, the current concentration in the mesa region 412 is alleviated and the electrical resistance of the mesa region 412 is reduced. Thereby, the on-resistance of the semiconductor device 401 is reduced.

As shown in FIG. 7, in the semiconductor device 401 of the present embodiment, the size w1 of the first region 412a in the first direction X is smaller than the size w2 of the source electrode recess 422 in the first direction X. In the present embodiment, when the size of the first region 412a in the first direction X is too large, the center part of the first region 412a in the first direction X may be separated from the contact part 452b and the electric field strength may increase. According to the present embodiment, it is easy to make the size w1 of the first region 412a in the first direction X sufficiently smaller than the size of the contact part 452b provided in the source electrode recess 422. Thereby, it is possible to alleviate the electric field strength of the entire first region 412a in the first direction X and reduce the leakage current of the Schottky barrier diode S. Here, the size w1 of the first region 412a in the first direction X is preferably 1 μm or less and more preferably 500 nm or less. In addition, according to the present embodiment, when a large size w2 of the source electrode recess 422 in the first direction X is secured, the channel layer 14 positioned on both sides of the source electrode recess 422 in the second direction Y can be secured to be large in the first direction X. Thereby, it is possible to constitute the semiconductor device 401 with a low on-resistance.

In the semiconductor device 401 of the present embodiment, the concentrations of n-type impurities in the first region 412a and the second region 412b may be adjusted. For example, when the concentration of n-type impurities in the first region 412a is set to be lower than the concentration of n-type impurities in the drift region 11, it is possible to further alleviate the electric field strength of the first region 412a. In addition, when the concentration of n-type impurities in the channel layer 14 of the second region 412b is set to be lower than the concentration of n-type impurities in the drift region 11, the channel layer 14 is more easily depleted in the off state.

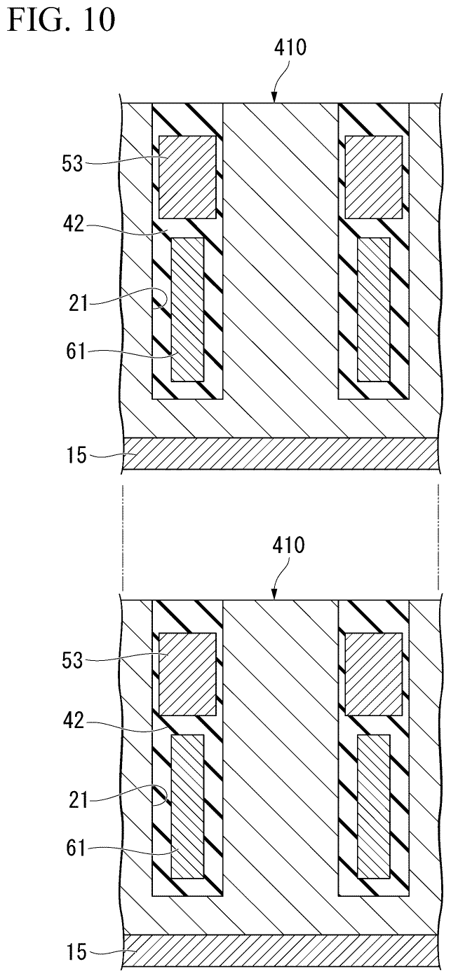

Next, the method of producing the semiconductor device 401 of the present embodiment will be described with reference to FIG. 10 to FIG. 20. Here, in FIG. 10 to FIG. 20, in each step, the first cross section is disposed on the upper side of the plane of the paper, and the second cross section is disposed on the lower side of the plane of the paper. That is, in each of FIG. 10 to FIG. 20, the cross section disposed on the upper side of the plane of the paper is the cross section along the line IIX-IIX in FIG. 7, and the cross section disposed on the lower side of the plane of the paper is the cross section along the line IX-IX in FIG. 7.

In the method of producing the semiconductor device 401 of the present embodiment, first, the semiconductor member 410 containing n-type impurities throughout is prepared. Next, n-type impurities are diffused into the lower end of the semiconductor member 410 to form the substrate part 15 with a high n-type impurity concentration. Here, the substrate part 15 may be prepared, and the semiconductor member 410 may be formed by epitaxial growth or the like. Next, as shown in FIG. 10, the gate electrode groove 21 is formed in the semiconductor member 410, and the field plate 61 and the gate electrode 53 embedded in the first insulating layer 42 are additionally formed inside the gate electrode groove 21.

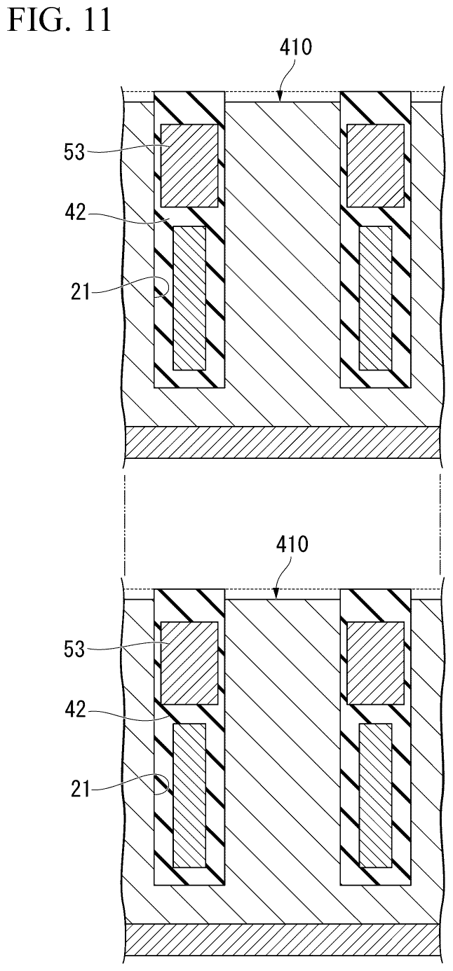

Next, as shown in FIG. 11, the upper surface of the semiconductor member 410 is etched. Thereby, the first insulating layer 42 protrudes from the upper surface of the semiconductor member 410.

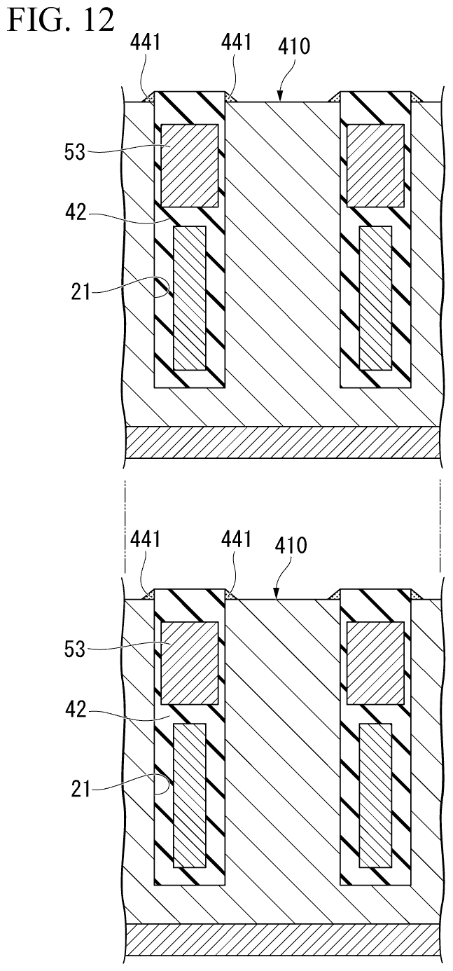

Next, as shown in FIG. 12, sidewalls 441 are formed on both the left and right sides of the upper end of the first insulating layer 42 protruding from the upper surface of the semiconductor member 410. The sidewall 441 is formed, for example, by forming an insulating film on the surfaces of the first insulating layer 42 and the semiconductor member 410 by a film forming method such as CVD and then etching the insulating film by anisotropic etching. After etching, the insulating film remaining on both the left and right sides of the upper end of the first insulating layer 42 serves as the sidewall 441.

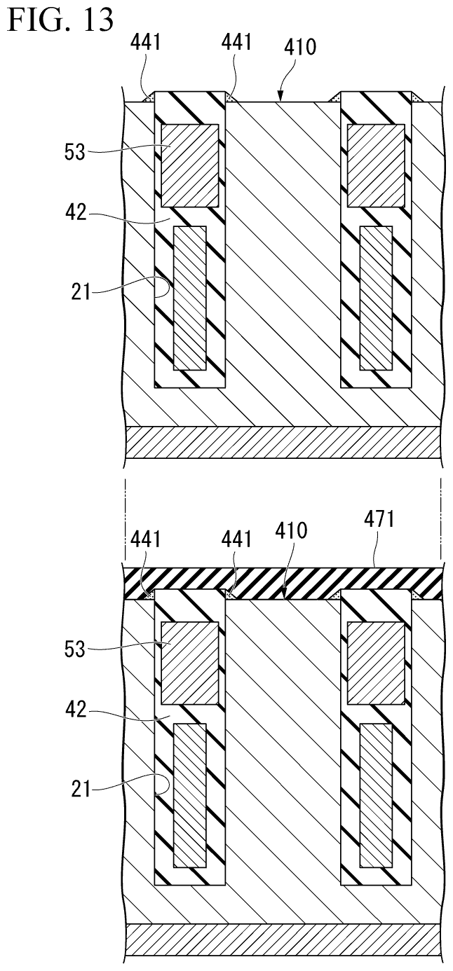

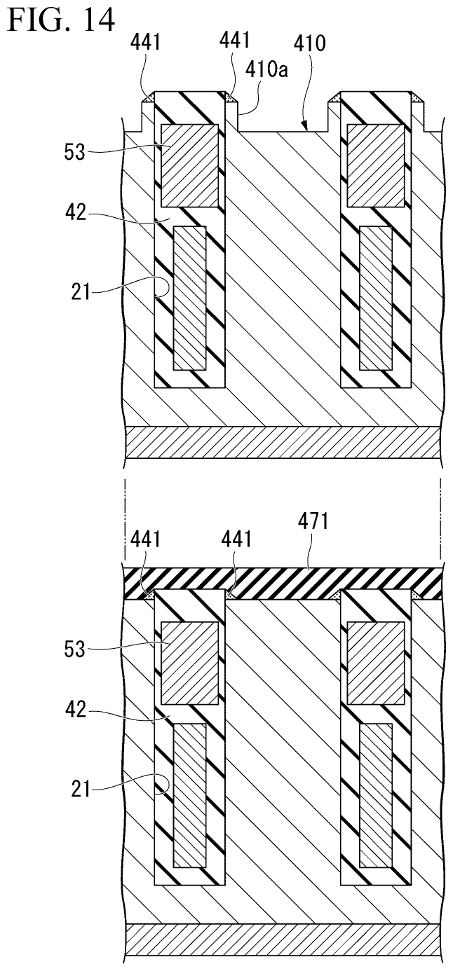

Next, as shown in FIG. 13, an insulating film 471 or a resist is selectively formed in the second cross section. In addition, as shown in FIG. 14, when the semiconductor member 410 is etched, a preliminary recess 410a is formed only in the first cross section of the semiconductor member 410. In addition, in this case, the sidewalls 441 function as a mask, and the parts of the semiconductor member 410 directly below the sidewalls 441 are not etched. Therefore, the preliminary recess 410a is formed in a region separated from the gate electrode groove 21 by the thickness of the sidewall 441 in the left to right direction.

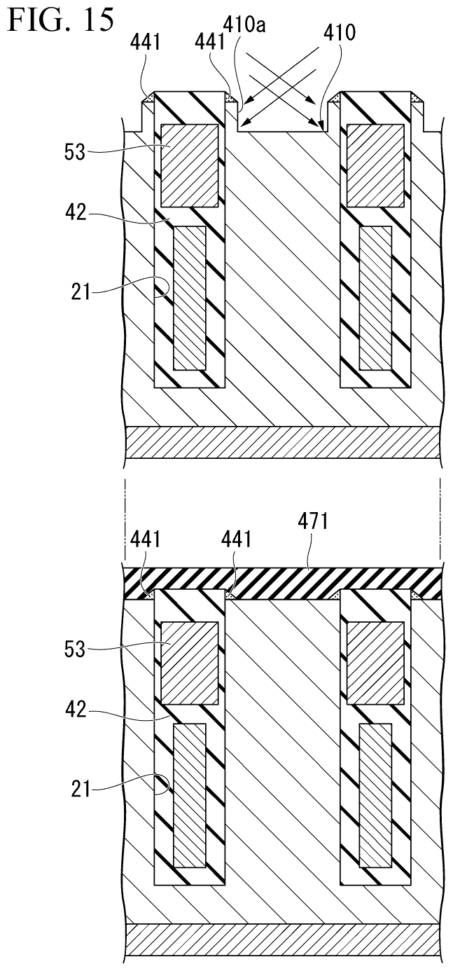

Next, as shown in FIG. 15, n-type impurities are ion-implanted into the upper surface of the semiconductor member 410. Thereby, the source layer 13 in which n-type impurities are diffused at a high concentration is formed on the upper part of the semiconductor member 410. In this case, the insulating film 471 formed on the upper surface of the semiconductor member 410 in the second cross section functions as a mask, and the source layer 13 is not formed in the semiconductor member 410 in the second cross section.

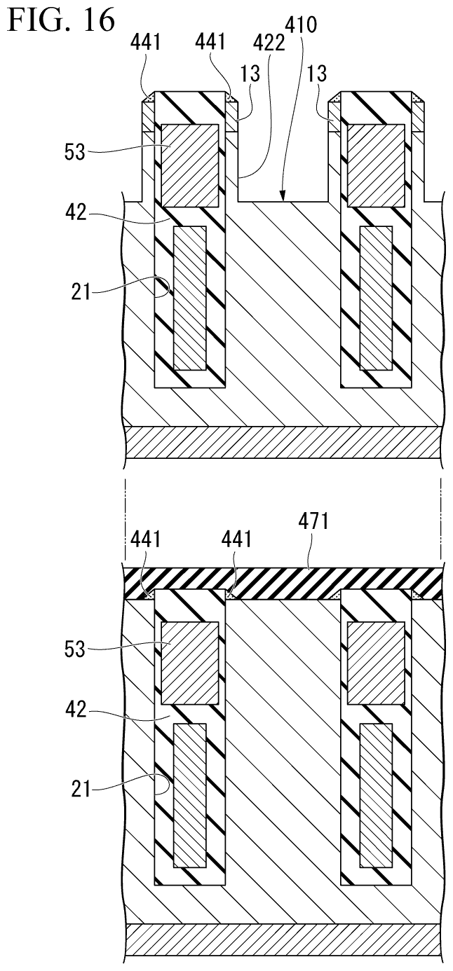

Next, as shown in FIG. 16, the semiconductor member 410 is etched only on the first cross section, and the source electrode recess 422 is formed in the semiconductor member 410. In this case, since the sidewall 441 functions as a mask, the source electrode recess 422 is formed in a region separated from the gate electrode groove 21 by the thickness of the sidewall 441 in the left to right direction. According to the present embodiment, the distance between the source electrode recess 422 and the gate electrode groove 21 can be accurately adjusted according to the size of the sidewall 441. Therefore, it is possible to accurately control the size of the channel layer 14 shown in FIG. 8 and it is possible to produce the semiconductor device 401 in which the variation in the gate threshold voltage is reduced.

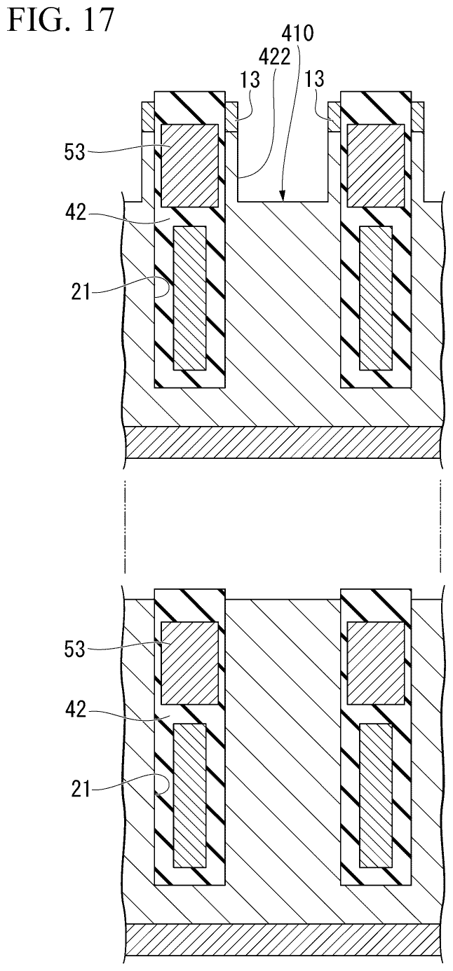

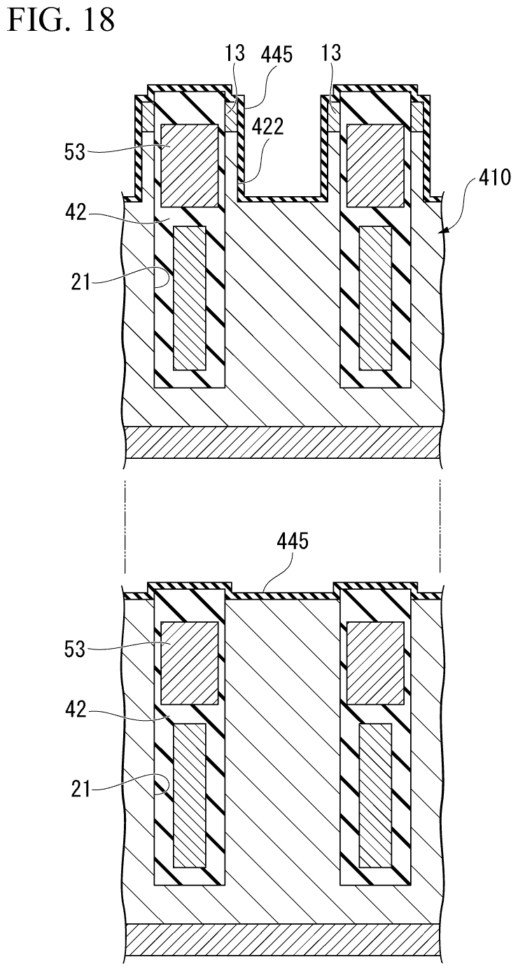

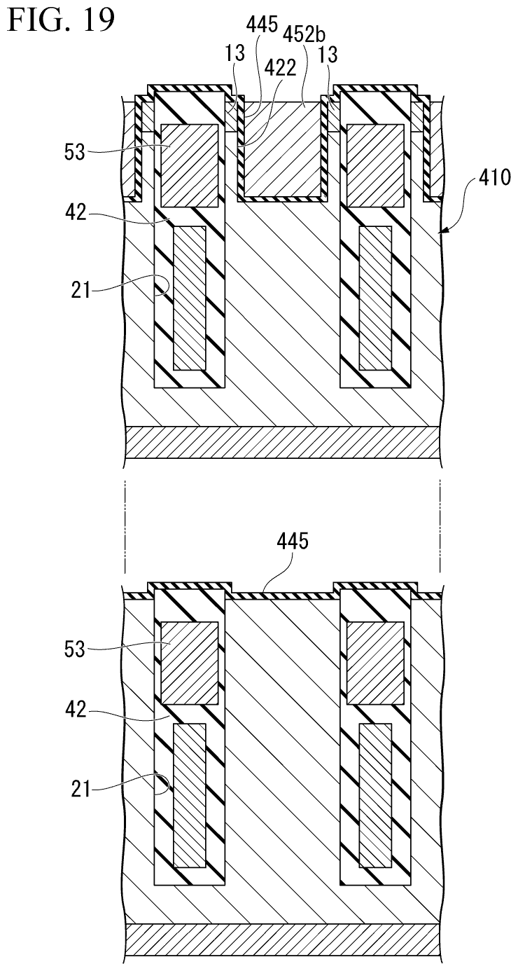

Next, as shown in FIG. 17, in the first cross section, the sidewall 441 is removed, and in the second cross section, the insulating film 471 is removed. Next, as shown in FIG. 18, the second insulating layer 445 is formed on the surface of the semiconductor member 410 and the first insulating layer 42. Next as shown in FIG. 19, the contact part 452b is formed inside the source electrode recess 422. In the step of forming the contact part 452b, for example, first, a film of a material constituting the contact part 452b is formed on the upper side of the semiconductor member 410 so that the source electrode recess 422 is filled. Next, the part of the film positioned above the source electrode recess 422 is removed by, for example, chemical mechanical polishing (CMP), and thus only the contact part 452b remains.

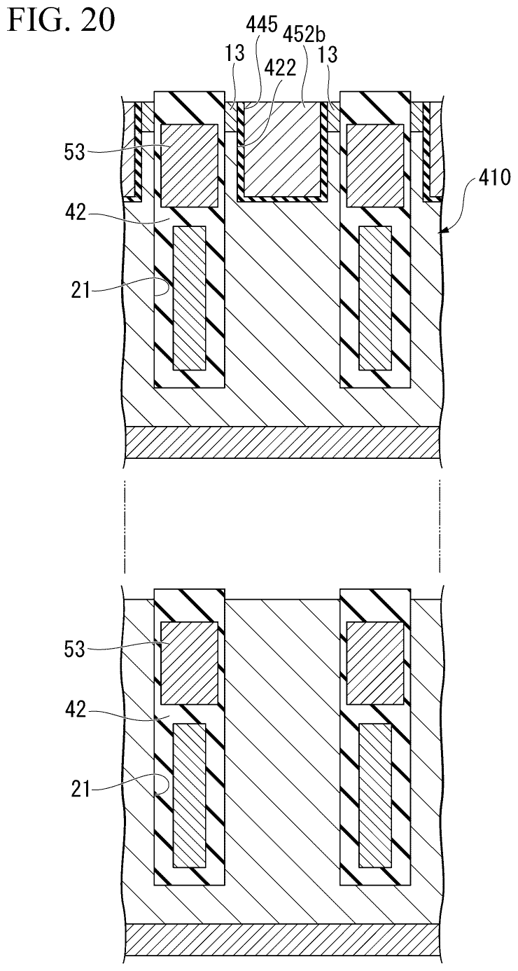

Next, as shown in FIG. 20, the second insulating layer 445 is etched until the source layer 13 is exposed. In addition, as shown in FIG. 8 and FIG. 9, the electrode part 52a is formed on the upper side of the semiconductor member 410, and the drain electrode 51 is formed on the lower side of the semiconductor member 410. In this manner, the semiconductor device 401 is obtained.

Here, the method of producing the semiconductor device 401 of the present embodiment is an example, and the semiconductor device 401 may be produced according to other procedures. Here, in this specification, the method of producing a semiconductor device has been described using the semiconductor device 401 of the fifth embodiment as an example. However, the semiconductor devices 1, 101, 201, and 301 of the other embodiments can be produced by appropriately modifying the steps of the production method of the fifth embodiment according to the configuration of each embodiment.

According to at least one of the embodiments described above, when the Schottky junctions 32, 132, 232, 332, and 432 positioned above the lower ends of both the source electrode 52 and the gate electrode 53 are provided, it is possible to reduce the leakage current of the Schottky barrier diode S.

While certain embodiments have been described, these embodiments have been presented only as exemplary examples, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device in which three mutually intersecting directions are defined as a first direction, a second direction and a third direction, one side in the third direction is defined as a first side, and the other side is defined as a second side, comprising:
a semiconductor member having a groove part that extends in the first direction, is arranged in the second direction, and is recessed toward the first side, and a recess that is positioned between a pair of the groove parts in the second direction and is recessed toward the first side;
a drain electrode that is positioned on the first side of the semiconductor member;
a gate electrode that is disposed inside the groove part;
a source electrode of which at least a part is disposed inside the recess;
a first insulating layer that is disposed inside the groove part and positioned between an inner surface of the groove part and the gate electrode; and
a second insulating layer that is disposed inside the recess and positioned between an inner surface of the recess and the source electrode,
wherein the semiconductor member has a drift region having first conductivity type impurities and positioned on the first side relative to a bottom of the groove part and
a mesa region having the first conductivity type impurities and positioned between the pair of groove parts in the second direction,
wherein the mesa region has a Schottky junction that forms a Schottky junction with the source electrode, and
wherein the Schottky junction is positioned on the second side relative to an end on the first side of the source electrode and on the second side relative to an end on the first side of the gate electrode.

2. The semiconductor device according to claim 1,
wherein the mesa region has a source layer having a higher concentration of the first conductivity type impurities than the drift region at an end on the second side, and
wherein the source layer has an ohmic junction that forms an ohmic junction with the source electrode.

3. The semiconductor device according to claim 2,
wherein one side in the second direction is defined as a third side, and the other side is defined as a fourth side,
wherein the mesa region has a first region positioned on the third side of the recess, and
a second region positioned on the fourth side of the recess and having the source layer, and
wherein the Schottky junction is provided in the first region.

4. The semiconductor device according to claim 2,
wherein the mesa region has a first region and a second region which are positioned between the groove part and the recess in the second direction and arranged in the first direction,
wherein the second region has the source layer, and
wherein the Schottky junction is provided in the first region.

5. The semiconductor device according to claim 3,
wherein the Schottky junction is positioned on the second side relative to an end on the second side of the gate electrode.

6. The semiconductor device according to claim 2,
wherein one side in the second direction is defined as a third side, and the other side is defined as a fourth side,
wherein the semiconductor member has a pair of the recesses positioned between the pair of groove parts and arranged in the second direction,
wherein the mesa region has a first region positioned between the pair of recesses, and
a second region positioned on the third side and the fourth side of the pair of recesses,
wherein the second region has the source layer, and
wherein the Schottky junction is provided in the first region.

7. The semiconductor device according to claim 2,
wherein the semiconductor member has a plurality of the recesses positioned between the pair of groove parts and arranged in the first direction,
wherein the mesa region has a first region positioned between the plurality of recesses in the first direction, and
a second region positioned between the groove part and the recess in the second direction and having the source layer, and
wherein the Schottky junction is provided in the first region.

8. The semiconductor device according to claim 7,
wherein a size of the first region in the first direction is smaller than a size of the recesses in the first direction.

9. The semiconductor device according to claim 3,
wherein a concentration of the first conductivity type impurities in the first region is lower than a concentration of the first conductivity type impurities in the drift region.

10. The semiconductor device according to claim 3,
wherein the second region has a channel layer positioned on the first side of the source layer, and
wherein a concentration of the first conductivity type impurities in the channel layer is lower than a concentration of the first conductivity type impurities in the drift region.

11. The semiconductor device according to claim 2,
wherein the source electrode has a contact part disposed inside the recess,
wherein an end on the second side of the inner surface of the recess is exposed from the second insulating layer, and
wherein the contact part has a first part that forms a Schottky junction with the mesa region at an end on the second side of the recess, and
a second part that forms an ohmic junction with the source layer at the end on the second side of the recess.

12. The semiconductor device according to claim 1, further comprising
a conductive member that is positioned inside the groove part and between the gate electrode and the drift region, and
wherein the conductive member is insulated from the gate electrode and electrically connected to the source electrode.
